(19) United States
(12) Patent Application Publication
(10) Pub. No.: US 2026/0156738 A1
(43) Pub. Date: Jun. 4, 2026

(54) WIRING SUBSTRATE

(71) Applicant: IBIDEN CO., LTD., Gifu (JP)

(72) Inventors: Nobuhisa KURODA, Gifu (JP); Ayumu KUBOTA, Gifu (JP); Toshihide MAKINO, Gifu (JP)

(73) Assignee: IBIDEN CO., LTD., Gifu (JP)

(21) Appl. No.: 19/398,679

(22) Filed: Nov. 24, 2025

(30) Foreign Application Priority Data
Dec. 4, 2024 (JP) 2024-211519

(51) Int. Cl. H05K 1/02; H05K 1/03; H05K 1/11; H05K 3/00

(52) U.S. Cl. CPC H05K 1/0271; H05K 1/0306; H05K 1/116; H05K 3/0029; H05K 2201/068; H05K 2201/094; H05K 2201/09481; H05K 2201/09527; H05K 2201/09536; H05K 2201/09609

(57) ABSTRACT

A wiring substrate includes a core part including a glass plate, a first build-up part including conductor layers and insulating layers, and a second build-up part including conductor layers and insulating layers. Each of the first and second build-up parts is formed such that the conductor layers include four conductor layers and the insulating layers include four insulating layers, the core part includes through-hole conductors formed in the glass plate such that the through-hole conductors connect the conductor layers in the first build-up part on the first surface and the second build-up part on the second surface of the glass plate, and the glass plate has a thickness in the range of 0.4 mm to 1.2 mm and a thermal expansion coefficient in the range of 3 ppm/° C. to 5 ppm/° C., and that a minimum pitch of the through-hole conductors is in the range of 200 μm to 400 μm.

### CROSS-REFERENCE TO RELATED APPLICATIONS

The present application is based upon and claims the benefit of priority to Japanese Patent Application No. 2024-211519, filed Dec. 4, 2024, the entire contents of which are incorporated herein by reference.

### BACKGROUND OF THE INVENTION

Field of the Invention The present invention relates to a wiring substrate.

### Description of Background Art

Japanese Patent Application Laid-Open Publication No. 2024-118643 describes a wiring substrate. The entire contents of this publication are incorporated herein by reference.

### SUMMARY OF THE INVENTION

According to one aspect of the present invention, a wiring substrate includes a core part including a glass plate, a first build-up part formed on a first surface of the glass plate and including conductor layers and insulating layers, and a second build-up part formed on a second surface of the glass plate on the opposite side with respect to the first surface and including conductor layers and insulating layers. Each of the first and second build-up parts is formed such that the conductor layers include four conductor layers and that the insulating layers include four insulating layers, the core part includes through-hole conductors formed in the glass plate such that the through-hole conductors connect the conductor layers in the first build-up part on the first surface of the glass plate and the conductor layers in the second build-up part on the second surface of the glass plate, and the core part is formed such that the glass plate has a thickness in the range of 0.4 mm to 1.2 mm and a thermal expansion coefficient in the range of 3 ppm/° C. to 5 ppm/° C., and that a minimum pitch of the through-hole conductors is in the range of 200 μm to 400 μm.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2 is a plan view illustrating a surface of a core part of a wiring substrate according to an embodiment of the present invention;

FIG. 3A is a cross-sectional view illustrating an example of a manufacturing process of a wiring substrate according to an embodiment of the present invention;

FIG. 3B is a cross-sectional view illustrating an example of a manufacturing process of a wiring substrate according to an embodiment of the present invention;

FIG. 3C is a cross-sectional view illustrating an example of a manufacturing process of a wiring substrate according to an embodiment of the present invention;

FIG. 3D is a cross-sectional view illustrating an example of a manufacturing process of a wiring substrate according to an embodiment of the present invention;

FIG. 3E is a cross-sectional view illustrating an example of a manufacturing process of a wiring substrate according to an embodiment of the present invention;

FIG. 3F is a cross-sectional view illustrating an example of a manufacturing process of a wiring substrate according to an embodiment of the present invention;

FIG. 3G is a cross-sectional view illustrating an example of a manufacturing process of a wiring substrate according to an embodiment of the present invention; and

FIG. 3H is a cross-sectional view illustrating an example of a manufacturing process of a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

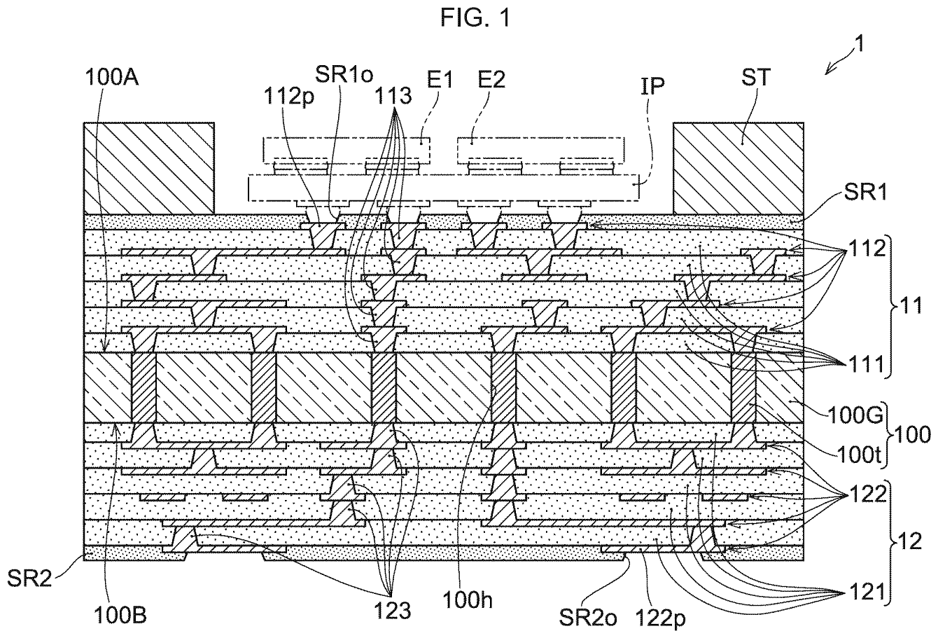

FIG. 1 illustrates a cross-sectional view of a wiring substrate 1, which is an example of a wiring substrate according to an embodiment of the present invention. The wiring substrate 1 has a core part 100 having a first surface (100A) and a second surface (100B) on an opposite side with respect to the first surface (100A). The core part 100 is composed of a glass plate (100G) and through-hole conductors (100t) formed by filling through holes (100h) formed in the glass plate (100G) with a conductor.

The wiring substrate of the embodiment has build-up parts that are respectively formed on both surfaces of the core part, each including 4 or more insulating layers and 4 or more conductor layers. The first surface (100A) and the second surface (100B) are each composed of a surface of the glass plate (100G) and surfaces of the through-hole conductors (100t). A first build-up part 11 is formed on the first surface (100A). A second build-up part 12 is formed on the second surface (100B).

In the description of the wiring substrate of the present embodiment, a side farther from the core part 100 is also referred to as “upper,” “upper side,” “outer side,” or “outer,” and a side closer to the core part 100 is also referred to as “lower,” “lower side,” “inner side,” or “inner.” Further, for the insulating layers and the conductor layers, a surface facing away from the core part 100 is also referred to as an “upper surface,” and a surface facing the core part 100 side is also referred to as a “lower surface.” Therefore, for example, in the description of the structural elements of the first build-up part 11 and the second build-up part 12, a side farther from the core part 100 is also referred to as an “upper side,” “upper-layer side,” or “outer side,” or simply “upper” or “outer,” and a side closer to the core part 100 is also referred to as a “lower side,” “lower-layer side,” or “inner side,” or simply “lower” or “inner.”

The first build-up part 11 is composed of insulating layers 111 and conductor layers 112 that are alternately laminated on the first surface (100A) of the core part 100. The second build-up part 12 is composed of insulating layers 121 and conductor layers 122 that are alternately laminated on the second surface (100B) of the core part 100. Each insulating layer 111 constituting the first build-up part 11 includes via conductors 113 that connect conductors (conductor layers 112, or a conductor layer 112 and a through-hole conductor (100t)) formed on opposite sides of the insulating layer 111 in a thickness direction. Each insulating layer 121 constituting the second build-up part 12 includes via conductors 123 that connect conductors (conductor layers 122, or a conductor layer 122 and a through-hole conductor (100t)) formed on opposite sides of the insulating layer 121 in the thickness direction.

A solder resist layer (SR1) is formed on the first build-up part 11. A solder resist layer (SR2) is formed on the second build-up part 12. Openings (SR10) are formed in the solder resist layer (SR1), and conductor pads (112p) of the outermost conductor layer 112 in the first build-up part 11 are exposed from the openings (SR10). Openings (SR20) are formed in the solder resist layer (SR2), and conductor pads (122p) of the outermost conductor layer 122 in the second build-up part 12 are exposed from the openings (SR20).

The conductor pads (112p) can be connection pads used for mounting an external electronic component or the like. As illustrated, the conductor pads (112p) can be electrically and mechanically connected, for example, by a bonding material such as solder, to connection pads of an external element (IP), which can be, for example, a silicon interposer. In the illustrated example, a component (E1) and a component (E2), which are electronic components such as active components such as semiconductor integrated circuit devices or transistors (for example, logic chips or memory elements), are connected on the external element (IP). That is, electronic components can be mounted on the wiring substrate 1 via an interposer. On the other hand, the conductor pads (122p) can be connection pads used for connection to any substrate (such as an external motherboard), an electrical component, or a mechanical component (not illustrated).

In the illustrated example, a reinforcing material (ST) is provided on the solder resist layer (SR1). The reinforcing material (ST) is provided so as to surround a region where the external element (IP) is mounted while avoiding a region where the conductor pads (112p) are provided, so as not to hinder mounting of components on the surface of the wiring substrate 1. By providing the reinforcing material (ST), deformation such as warpage or bending of the wiring substrate 1 can be suppressed. By suppressing deformation of the wiring substrate 1, mounting of the external element (IP) on the wiring substrate 1 can be achieved with high reliability.

The glass plate (100G) constituting the core part 100 is formed of glass selected from soda lime glass, aluminosilicate glass, and borosilicate glass. The glass plate (100G) may contain, as additives, magnesium, calcium, manganese, aluminum, lead, iron, chromium, potassium, sulfur, antimony, boron, or the like. In the wiring substrate of the embodiment, the glass plate (100G) has a relatively low thermal expansion coefficient of 3 ppm/° C. or more and 5 ppm/° C. or less.

The insulating layers 111 constituting the first build-up part 11 and the insulating layers 121 constituting the second build-up part 12 are each formed, for example, using an insulating resin such as epoxy resin, bismaleimide triazine resin (BT resin), or phenol resin. The insulating layers (111, 121) may each contain a reinforcing material (base material) such as glass fiber and/or an inorganic filler such as silica or alumina. The insulating layers (111, 121) have a thermal expansion coefficient of, for example, 15 ppm/° C. or more and 25 ppm/° C. or less.

The solder resist layers (SR1, SR2) are formed using, for example, a photosensitive epoxy resin or polyimide resin, or the like. As a material for the reinforcing material (ST), any material capable of suppressing deformation of the wiring substrate 1 may be used. A metallic material such as a copper alloy, an aluminum alloy, or an iron alloy can be used. However, it is preferable that the reinforcing material be formed of a material with high rigidity. For example, stainless steel is used.

The conductor layers (112, 122), the via conductors (113, 123), and the through-hole conductors (100t) can be formed using any metal such as copper or nickel. For example, the conductor layers (112, 122) can each be formed using a metal foil such as a copper foil and/or a metal film formed by plating or sputtering. In FIG. 1, the conductor layers (112, 122), the via conductors (113, 123), and the through-hole conductors (100t) are illustrated in a simplified manner as each having a single-layer structure for ease of viewing, but can each have a multilayer structure including two or more layers. The conductor layers (112, 122), the via conductors (113, 123), and the through-hole conductors (100t) can each have a two-layer structure including a metal film layer (for example, an electroless copper plating film) and a plating film layer (for example, an electrolytic copper plating film). The conductor layers (112, 122) included in the wiring substrate 1 are each patterned to have predetermined conductor patterns.

The through-hole conductors (100t) constituting the core part 100 connect the conductor layers 112 constituting the first build-up part 11 and the conductor layers 122 constituting the second build-up part 12. In the illustrated example, the through-hole conductors (100t) are directly connected to the via conductors 113 and thereby connected to the conductor layers 112 via the via conductors 113, and are directly connected to the via conductors 123 and thereby connected to the conductor layers 122 via the via conductors 123.

The through-hole conductors (100t) are composed of a conductive material that entirely fills the through holes (100h) formed in the glass plate (100G). In the illustration, the through holes (100h) are formed to have substantially the same dimension in a thickness direction of the glass plate (100G). However, the through holes (100h) (and thus the through-hole conductors (100t)) can also have a structure that is reduced in diameter toward a center portion in the thickness direction of the glass plate (100G) from both the first surface (100A) side and the second surface (100B) side.

Here, for convenience, the term “reduced in diameter” is used. However, an opening shape of each through hole (100h) in plan view is not necessarily limited to a circular shape. The term “diameter” refers to a linear distance between two most distant points on an outer edge of an object when the object is viewed in plan view. The term “reduced in diameter” means that a linear distance between two most distant points on an outer edge in a horizontal cross section of each through hole (100h) becomes smaller. The term “in plan view” means viewing an object along the thickness direction of the wiring substrate 1 (that is, the thickness direction of the glass plate (100G)).

As described above, in the wiring substrate of the embodiment, the glass plate (100G) has a relatively low thermal expansion coefficient of 3 ppm/° C. or more and 5 ppm/° C. or less. When the core part 100 includes such a glass plate (100G) having a relatively low thermal expansion coefficient, the degree of warpage that may occur in the wiring substrate 1 can be reduced and the thickness of the core part 100 (that is, the thickness of the glass plate (100G)) can be made relatively small, at 0.4 mm or more and 1.2 mm or less. Both reduction in warpage and thinning of the wiring substrate can be achieved. In such a glass plate (100G) having a relatively low thermal expansion coefficient and a small thickness, cracks may easily occur when a distance (formation pitch) between adjacent through-hole conductors (100t) (through holes (100h)) among the multiple through-hole conductors (100t) (through holes (100h)) is small. To address such a problem, in the wiring substrate of the embodiment, crack occurrence in the glass plate is suppressed by setting the formation pitch between the through-hole conductors (through holes) to a predetermined value or more.

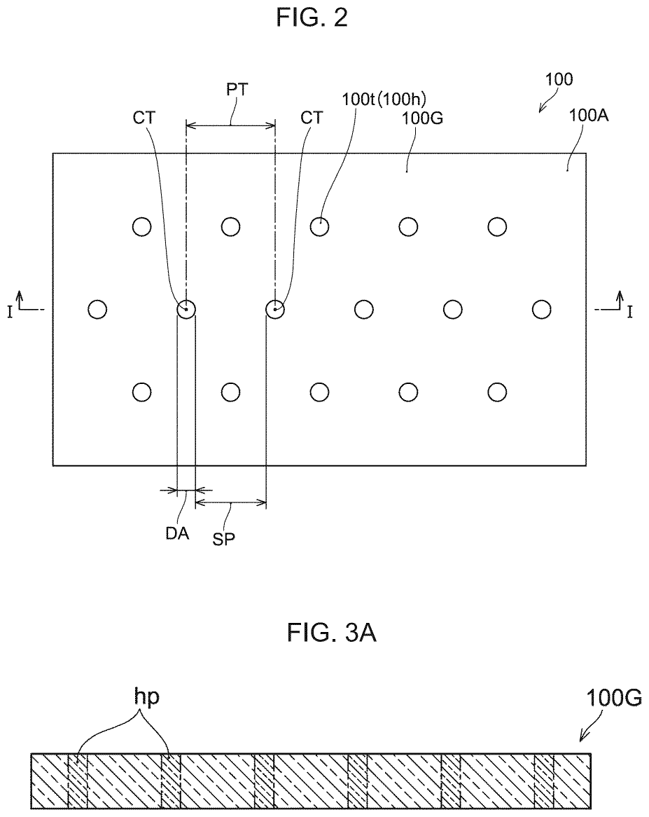

Next, with reference to FIG. 2, formation of the through-hole conductors (100t) (through holes (100h)) for suppressing crack occurrence in the glass plate (100G) is specifically described. FIG. 2 illustrates a top view of the first surface (100A) of the core part 100 of the wiring substrate 1 illustrated in FIG. 1, with the structural elements on the upper side of the core part 100 removed. Therefore, in FIG. 2, the surface of the glass plate (100G) and the surfaces of the through-hole conductors (100t), which constitute the first surface (100A) of the core part 100, are exposed. FIG. 1 is a cross-sectional view of the wiring substrate 1 taken along a line (I-I) in FIG. 2. Further, the wiring substrate 1 is formed to have a rectangular shape in plan view with each side measuring 50 mm or more, and therefore, the glass plate (100G) similarly has a rectangular shape with each side measuring 50 mm or more.

In the wiring substrate of the embodiment, among the multiple through-hole conductors (100t) included in the core part 100, a shortest distance (that is, a formation pitch) (PT) between centers (CT) of two adjacent through-hole conductors (100t) is set to 200 μm or more and 400 μm or less. By setting the formation pitch between the through-hole conductors (100t) to the above value, local concentration of stress caused by, for example, a difference between a thermal expansion coefficient of the glass material constituting the glass plate (100G) and a thermal expansion coefficient of the conductive material constituting the through-hole conductors (100t) can be avoided. Crack occurrence in the glass plate (100G) can be suppressed. Here, the “center” of each through-hole conductor (100t) refers to a midpoint of a straight line connecting two most distant points on an outer edge of the through-hole conductor (100t) in plan view. Further, the center (CT) and formation pitch (PT) of the through-hole conductors (100t) may be replaced with the center CT and formation pitch of the through holes (100h).

A diameter (DA) of each through-hole conductor (100t) at the two surfaces (the first surface (100A) and the second surface (100B)) orthogonal to the thickness direction of the glass plate (100G) refers to a maximum diameter of each through hole (100h) or through-hole conductor (100t), and is, for example, 50 μm or more and 150 μm or less.

From a point of view of suppressing crack occurrence in the glass plate (100G) by suppressing stress and strain caused by thermal expansion of the through-hole conductors (100t), the diameter (DA) of the through-hole conductors (100t) is preferably 100 μm or less.

Further, a shortest distance between outer edges of adjacent through-hole conductors (100t) at the two surfaces (the first surface (100A) and the second surface (100B)) orthogonal to the thickness direction of the glass plate (100G) (that is, a space (SP) between the through-hole conductors (100t)) is, for example, 50 μm or more and 150 μm or less. From a point of view of effectively dispersing stress caused by thermal expansion of the through-hole conductors (100t) in the glass plate (100G) and suppressing crack occurrence in the glass plate (100G), the space (SP) between adjacent through-hole conductors (100t) is preferably 100 μm or more.

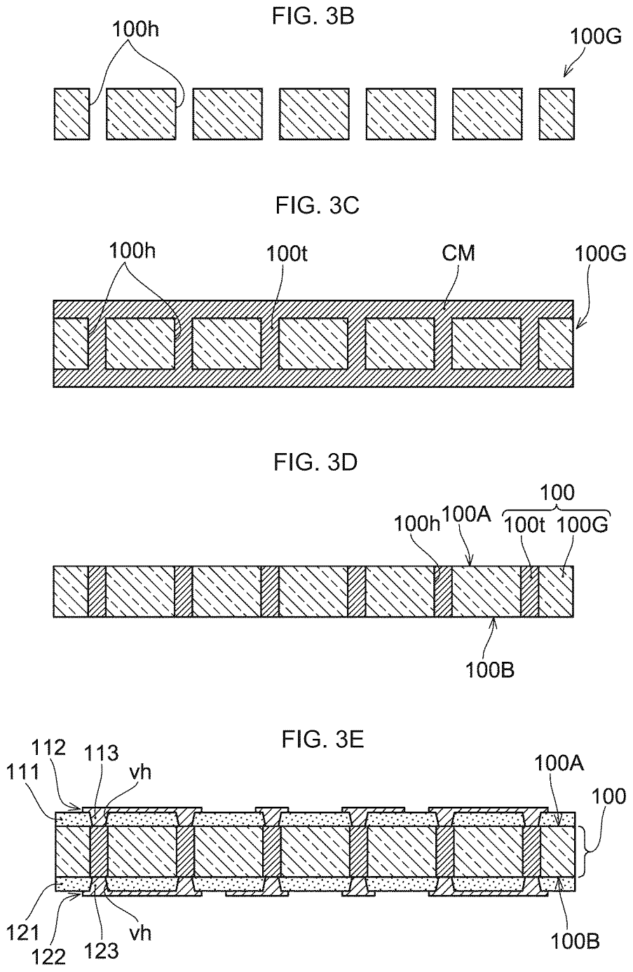

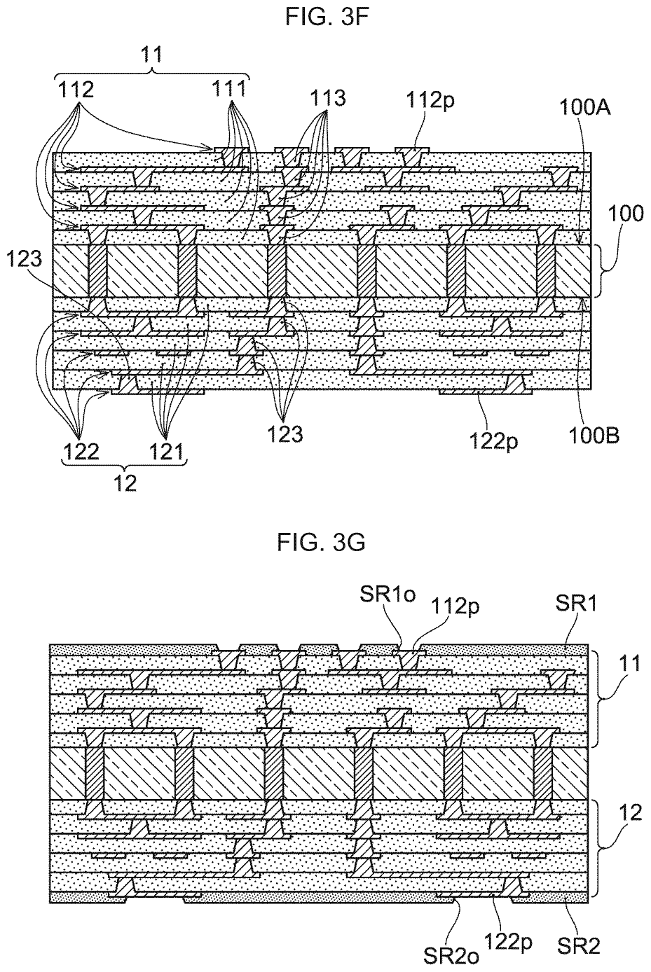

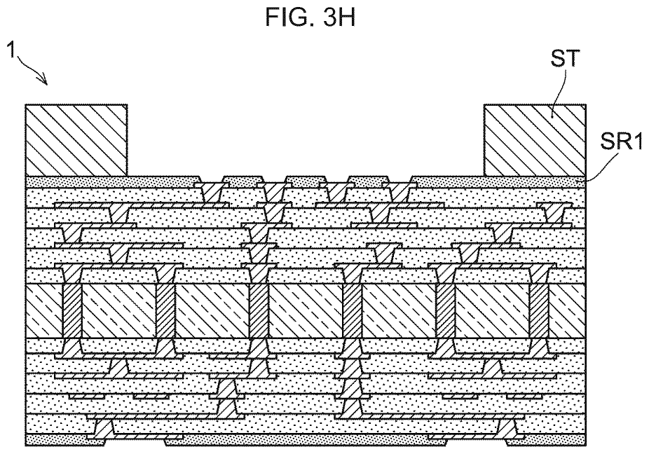

Next, an example of a method for manufacturing a wiring substrate is described with reference to FIGS. 3A to 3H using a case where the wiring substrate 1 of FIG. 1 is manufactured as an example. In FIGS. 3A to 3H, as in FIG. 1, the conductor layers are simplified in structure and illustrated as each having a single-layer structure.

First, as illustrated in FIG. 3A, the glass plate (100G) is prepared. The prepared glass plate (100G) has a thermal expansion coefficient of 3 ppm/° C. or more and 5 ppm/° C. or less. As the glass plate (100G) having a thermal expansion coefficient in this range, for example, a plate made of glass selected from soda lime glass, aluminosilicate glass, borosilicate glass, and the like may be prepared. Further, the glass plate (100G) has a thickness of 0.4 mm or more and 1.2 mm or less. The glass plate (100G) has a rectangular shape in plan view with each side measuring 50 mm or more.

Modified portions (hp) are formed by laser light irradiation at positions where the through holes (100h) are to be formed in the glass plate (100G) (see FIG. 3B). As the laser light, helium-neon lasers, argon ion lasers, excimer lasers, various YAG lasers, and the like can be used. Each modified portion (hp) is a portion in which the glass structure has been altered, and it is more easily removed by a subsequent etching process. Among the multiple modified portions (hp) that are formed, a shortest distance (formation pitch) between centers of two adjacent modified portions (hp) is 200 μm or more and 400 μm or less, and stress and strain that may occur in the glass plate (100G) due to heat generated by laser light irradiation is suppressed. Crack occurrence in the glass plate (100G) during the process of forming the modified portions (hp) by laser light irradiation can be suppressed.

Subsequently, the modified portions (hp) are removed using an etching solution containing, for example, an aqueous hydrofluoric acid solution. Specifically, the modified portions (hp) are removed by immersing the glass plate (100G), in which the modified portions (hp) have been formed, in an etching solution containing, for example, an aqueous hydrofluoric acid solution. The concentration of the aqueous hydrofluoric acid solution is appropriately adjusted so that etching proceeds sufficiently. Further, from a point of view of promoting etching, hydrochloric acid and/or nitric acid may be included in the etching solution, and ultrasonic waves may be propagated to an etching bath during etching of the glass plate (100G). As illustrated in FIG. 3B, the through holes (100h) are formed in the portions from which the modified portions (hp) have been removed. The formed through holes (100h) have a diameter of, for example, 50 μm or more and 150 μm or less. Further, among the formed multiple through holes (100h), a shortest distance between two adjacent through holes (100h) is, for example, 50 μm or more and 150 μm or less.

Next, as illustrated in FIG. 3C, the through holes (100h) are filled with a conductive material (CM). The conductive material (CM) is formed so as to completely fill the through holes (100h) and completely cover the two surfaces of the glass plate (100G) that are orthogonal to the thickness direction. In forming the conductive material (CM), first, a metal film layer (not illustrated) is formed on inner wall surfaces of the through holes (100h) and on the two surfaces of the glass plate (100G), for example, by electroless plating. Subsequently, a plating film layer is formed on the metal film layer by electrolytic plating using the metal film layer as a power feeding layer, and the through-hole conductors (100t) having a two-layer structure (illustrated as a single layer in the drawing) including the metal film layer and the plating film layer are formed in the through holes (100h), and the two surfaces of the glass plate (100G) are covered with layers of the conductive material (CM) having a two-layer structure (illustrated as a single layer in the drawing) including the metal film layer and the plating film layer.

Next, the layers of the conductive material (CM) covering the two surfaces of the glass plate (100G) that are orthogonal to the thickness direction are removed by polishing. As illustrated in FIG. 3D, the surfaces of the glass plate (100G) and the surfaces of the through-hole conductors (100t) are exposed. The core part 100 having the first surface (100A) and the second surface (100B), which are composed of the surfaces of the glass substrate (100G) and the surfaces of the through-hole conductors (100t), is formed. The removal of the layers of the conductive material (CM) by polishing can be performed, for example, by chemical mechanical polishing (CMP).

Next, as illustrated in FIG. 3E, an insulating layer 111 is laminated on the first surface (100A) of the core part 100, and further, a conductor layer 112 is formed on the insulating layer 111. At the same time as the formation of the conductor layer 112, via conductors 113 are formed. Further, on the second surface (100B) of the core part 100, an insulating layer 121 is laminated, and a conductor layer 122 is formed on the insulating layer 121. At the same time as the formation of the conductor layer 122, via conductors 123 are formed.

The insulating layers (111, 121) are formed, for example, by thermocompression bonding of a film-shaped insulating resin (for example, epoxy resin) onto the surfaces (the first surface (100A) and the second surface (100B)) of the core part 100. The insulating layers have a thermal expansion coefficient of 15 ppm/° C. or more and 25 ppm/° C. or less. Through holes (vh) are formed, for example, by irradiation with CO₂ laser light at positions in the insulating resin where the via conductors (113, 123) are to be formed. The conductor layers (112, 122) and the via conductors (113, 123) are formed by forming a metal film layer (not illustrated) on inner surfaces of the through holes (vh) and on the upper surfaces of the insulating layers (111, 121) by electroless plating or sputtering, and performing electrolytic plating using the metal film layer as a power feeding layer and using a plating resist having appropriate openings. That is, the conductor layers (112, 122) and the via conductors (113, 123) are formed using a semi-additive process (SAP) method.

Next, as illustrated in FIG. 3F, on the upper side of the first surface (100A) of the core part 100, the same processes for forming the insulating layer 111, the conductor layer 112, and the via conductors 113 described above are repeated three or more times, and the first build-up part 11 including four or more insulating layers 111 and four or more conductor layers 112 is formed. Further, on the upper side of the second surface (100B) of the core part 100, the same processes for forming the insulating layer 121, the conductor layer 122, and the via conductors 123 described above are repeated three or more times, and the second build-up part 12 including four or more insulating layers 121 and four or more conductor layers 122 is formed. The outermost conductor layer 112 of the first build-up part 11 is patterned to include the conductor pads (112p). The outermost conductor layer 122 of the second build-up part 12 is patterned to include the conductor pads (122p).

Next, as illustrated in FIG. 3G, the solder resist layer (SR1) is formed on the first build-up part 11, and the solder resist layer (SR2) is formed on the second build-up part 12. The solder resist layers (SR1, SR2) are each formed, for example, by forming a resin layer containing a photosensitive epoxy resin or polyimide resin or the like and performing exposure and development using a mask having appropriate opening patterns. The solder resist layers (SR1, SR2) are formed to have the openings (SR10, SR20) that expose the conductor pads (112p, 122p). On exposed surfaces of the conductor pads (112p, 122p), a surface protection film (not illustrated) made of Au, Ni/Au, Ni/Pd/Au, solder, or heat-resistant preflux may be formed by electroless plating, solder leveling, spray coating, or the like.

Next, as illustrated in FIG. 3H, the reinforcing material (ST) is attached onto the solder resist layer (SR1). As the reinforcing material (ST), for example, a plate-shaped stainless steel material can be used. However, a metal material other than a stainless steel material may also be used. As the reinforcing material (ST), a plate-shaped metal material is used, having a planar shape formed into a shape along a contour of a region where a component is mounted on the wiring substrate 1 by punching or laser processing. The plate-shaped reinforcing material (ST) is bonded to the solder resist layer (SR1), for example, via a thermosetting adhesive (not illustrated). Through the above processes, the wiring substrate 1 is completed.

The wiring substrate of the embodiment is not limited to those having the structures illustrated in the drawings and those having the structures, shapes, and materials exemplified in the present specification. In the wiring substrate 1 described above, the first build-up part 11 and the second build-up part 12 each include five conductor layers and five insulating layers. However, the number of insulating layers and conductor layers included in the first and second build-up parts (11, 12) is not limited to this. The first build-up part 11 and the second build-up part 12 of the wiring substrate of the embodiment may each include four or more conductor layers and four or more insulating layers, and may include six or more conductor layers and six or more insulating layers. For example, the first build-up part 11 and the second build-up part 12 may have different numbers of insulating layers and conductor layers from each other.

Japanese Patent Application Laid-Open Publication No. 2024-118643 describes a wiring substrate. The wiring substrate has a core substrate that includes a substrate made of glass and through-hole conductors penetrating the substrate. On both sides of the core substrate, resin insulating layers and conductor layers are alternately laminated.

In the glass substrate, multiple through holes are formed, and depending on characteristics of the glass substrate, cracks may occur around the through holes.

A wiring substrate according to an embodiment of the present invention includes: a core part that includes a glass plate having a first surface and a second surface on an opposite side with respect to the first surface; and build-up parts that are respectively formed on the two surfaces of the glass plate and are each composed of laminated conductor layers and insulating layers. The build-up parts are each composed of four or more conductor layers and four or more insulating layers. The core part includes multiple through-hole conductors that connect the conductor layers in the build-up part formed on the first surface side and the conductor layers in the build-up part formed on the second surface side. The glass plate has a thickness of 0.4 mm or more and 1.2 mm or less and a thermal expansion coefficient of 3 ppm/° C. or more and 5 ppm/° C. or less. A minimum formation pitch of the multiple through-hole conductors is 200 μm or more and 400 μm or less.

According to an embodiment of the present invention, a wiring substrate of good quality can be provided in which crack occurrence in a glass plate constituting a core part is suppressed.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a core part comprising a glass plate;
a first build-up part formed on a first surface of the glass plate and comprising a plurality of conductor layers and a plurality of insulating layers; and
a second build-up part formed on a second surface of the glass plate on an opposite side with respect to the first surface and comprising a plurality of conductor layers and a plurality of insulating layers,
wherein each of the first and second build-up parts is formed such that the plurality of conductor layers includes four conductor layers and that the plurality of insulating layers includes four insulating layers, the core part includes a plurality of through-hole conductors formed in the glass plate such that the plurality of through-hole conductors is configured to connect the conductor layers in the first build-up part on the first surface of the glass plate and the conductor layers in the second build-up part on the second surface of the glass plate, and the core part is formed such that the glass plate has a thickness in a range of 0.4 mm to 1.2 mm and a thermal expansion coefficient in a range of 3 ppm/° C. to 5 ppm/° C., and that a minimum pitch of the through-hole conductors is in a range of 200 μm to 400 μm.

2. The wiring substrate according to claim 1, wherein the core part is formed such that the plurality of through-hole conductors has a shortest distance of 100 μm or more between adjacent through-hole conductors.

3. The wiring substrate according to claim 1, wherein the core part is formed such that a diameter of the through-hole conductors is 100 μm or less.

4. The wiring substrate according to claim 1, wherein the core part is formed such that the glass plate has a rectangular planar shape with each side measuring 50 mm or more.

5. The wiring substrate according to claim 1, wherein each of the first and second build-up parts is formed such that the insulating layers have a thermal expansion coefficient in a range of 15 ppm/° C. to 25 ppm/° C.

6. The wiring substrate according to claim 1, wherein the core part is formed such that the through-hole conductors comprise conductive material entirely filling through holes penetrating through the glass plate, respectively.

7. The wiring substrate according to claim 1, wherein the core part is formed such that the glass plate has a thickness in a range of 0.6 mm to 0.9 mm.

8. The wiring substrate according to claim 2, wherein the core part is formed such that a diameter of the through-hole conductors is 100 μm or less.

9. The wiring substrate according to claim 2, wherein the core part is formed such that the glass plate has a rectangular planar shape with each side measuring 50 mm or more.

10. The wiring substrate according to claim 2, wherein each of the first and second build-up parts is formed such that the insulating layers have a thermal expansion coefficient in a range of 15 ppm/° C. to 25 ppm/° C.

11. The wiring substrate according to claim 2, wherein the core part is formed such that the through-hole conductors comprise conductive material entirely filling through holes penetrating through the glass plate, respectively.

12. The wiring substrate according to claim 2, wherein the core part is formed such that the glass plate has a thickness in a range of 0.6 mm to 0.9 mm.

13. The wiring substrate according to claim 3, wherein the core part is formed such that the glass plate has a rectangular planar shape with each side measuring 50 mm or more.

14. The wiring substrate according to claim 3, wherein each of the first and second build-up parts is formed such that the insulating layers have a thermal expansion coefficient in a range of 15 ppm/° C. to 25 ppm/° C.

15. The wiring substrate according to claim 3, wherein the core part is formed such that the through-hole conductors comprise conductive material entirely filling through holes penetrating through the glass plate, respectively.

16. The wiring substrate according to claim 3, wherein the core part is formed such that the glass plate has a thickness in a range of 0.6 mm to 0.9 mm.

17. The wiring substrate according to claim 4, wherein each of the first and second build-up parts is formed such that the insulating layers have a thermal expansion coefficient in a range of 15 ppm/° C. to 25 ppm/° C.

18. The wiring substrate according to claim 4, wherein the core part is formed such that the through-hole conductors comprise conductive material entirely filling through holes penetrating through the glass plate, respectively.

19. The wiring substrate according to claim 4, wherein the core part is formed such that the glass plate has a thickness in a range of 0.6 mm to 0.9 mm.

20. The wiring substrate according to claim 5, wherein the core part is formed such that the through-hole conductors comprise conductive material entirely filling through holes penetrating through the glass plate, respectively.
